(19) United States
(12) Patent Application Publication
(10) Pub. No.: US 2025/0108972 A1
(43) Pub. Date: Apr. 3, 2025

(54) LARGE FORMAT RETICLE CONTAINER

(71) Applicant: ENTEGRIS, INC., Billerica, MA (US)

(72) Inventors: Huaping Wang, Eden Prairie, MN (US); Anthony M. Tieben, Belle Plaine, MN (US); Russ V. Raschke, Chanhassen, MN (US); Brian Wiseman, Glencoe, MN (US); Tyler Monforton, Chaska, MN (US)

(21) Appl. No.: 18/900,607

(22) Filed: Sep. 27, 2024

Related U.S. Application Data
(60) Provisional application No. 63/541,222, filed on Sep. 28, 2023.

(51) Int. Cl. B65D 85/68; B65D 25/10; B65D 77/04

(52) U.S. Cl. CPC B65D 85/68; B65D 25/101; B65D 77/0453; B65D 2585/6892

(57) ABSTRACT

A substrate container is provided including an inner pod configured to accommodate a large format reticle, and an outer pod configured to contain and secure the inner pod. The inner pod can be clamped together using a clip or features provided on the outer pod. Features of the outer pod that can clamp the inner pod include flanges, grooves, angled clamping surfaces, other clamping features, or clamping mechanisms. Clamping mechanisms can be actuated by physical, electrical, and/or magnetic features, such as placement of a door in an opening of a shell, operation of a door latch, or interaction of a tool to release the clamping mechanism using mechanical, electrical, and/or magnetic force.

### FIELD

This disclosure is directed to substrate containers configured to store and retain large-format reticles.

### BACKGROUND

Reticle containers typically include standard mechanical interface (SMIF) pods or combination pods including an inner pod and an outer pod shaped to accommodate a roughly square-shaped reticle.

### SUMMARY

This disclosure is directed to substrate containers configured to store and retain large-format reticles.

Reticles having larger sizes and/or different aspect ratios may offer superior lithography performance. Such reticles would not fit current reticle pods and/or the related automation for handling such reticle pods. The large format substrate containers provided herein can use standard interfaces while securely containing the reticles within an inner pod secured within the outer pod.

In traditional reticle pods, the outer pod can be opened by lifting a pod dome and/or dropping a pod door, thus opening in a vertical direction. The vertical opening and closing of the outer pod can facilitate clamping to retain the position and closure of the inner pod, and optionally further allow the reticle itself to be clamped. When using a pod suited for storage of the large format reticle, the outer pod may open horizontally. The substrate containers provided herein allow for clamping of the inner pod and, in embodiments, clamping of a reticle contained therein through suitable design of the outer pod and/or inclusion of clamping mechanisms therein. Accordingly, large format reticles can be secured even in horizontal-opening substrate containers.

In an embodiment, a substrate container includes an inner pod configured to contain a large format reticle. The inner pod includes a cover and a baseplate. The substrate container further includes an outer pod configured to contain the inner pod. The outer pod has an opening on a front side of the outer pod. The outer pod includes first flanges on opposing side walls, the first flanges configured to support the inner pod.

In an embodiment, the outer pod includes second flanges on said opposing side walls, the respective first flanges and second flanges on each respective side wall defining a groove configured to receive the inner pod such that the cover and the baseplate are clamped. In an embodiment, the respective first flanges and second flanges are angled with respect to one another. In an embodiment, the inner pod includes one or more reticle retention features, and the outer pod includes one or more securement features configured to, when the inner pod is inserted into the outer pod, actuate the reticle retention features such that a reticle is clamped within the inner pod.

In an embodiment, a substrate container includes an inner pod configured to contain a large format reticle. The inner pod includes a cover and a baseplate. The substrate container further includes an outer pod configured to contain the inner pod. The outer pod includes a shell having an opening on a front side of the outer pod and a door configured to be secured so as to cover the opening. The shell includes a first angled clamping surface and the door including a second angled clamping surface. The first angled clamping surface and the second angled clamping surface are configured to clamp the cover and the baseplate when the door is secured to the shell. The first angled clamping surface and the second angled clamping surface are configured to support the inner pod when the inner pod is oriented vertically or oriented at an angle to a horizontal direction.

In an embodiment, one of the first clamping surface or the second clamping surface further comprises an inner pod retainer configured to maintain an alignment of the cover and the baseplate when the inner pod rests on the second angled clamping surface. In an embodiment, the inner pod includes one or more reticle retention features, and at least one of the first angled clamping surface and the second angled clamping surface is configured to interface with at least some of the one or more reticle retention features such that said at least some of the one or more reticle retention features are actuated to clamp a reticle within the inner pod.

In an embodiment, a substrate container includes an inner pod configured to contain a large format reticle. The inner pod includes a cover and a baseplate. The substrate container further includes an outer pod configured to contain the inner pod. The outer pod includes a shell having an opening on a front side of the outer pod. The substrate container further includes a clip configured to be attached to the inner pod such that the clip clamps the cover to the baseplate.

In an embodiment, the outer pod includes one or more supports configured to receive one or more portions of the clip such that the clip is supported when the clip is attached to the inner pod and the inner pod is inserted into the outer pod. In an embodiment, the outer pod includes one or more supports configured to contact the inner pod such that the inner pod is supported by contact with the supports when the clip is attached to the inner pod and the inner pod is inserted into the outer pod. In an embodiment, the inner pod includes one or more reticle retention features, and the clip is configured to contact the one or more reticle retention features such the one or more reticle retention features are actuated to clamp a reticle within the inner pod.

In an embodiment, a substrate container includes an inner pod configured to contain a large format reticle. The inner pod includes a cover and a baseplate. The substrate container further includes an outer pod configured to contain the inner pod. The outer pod includes a shell having an opening on a front side of the outer pod and a door. The door includes a latch, a latch interface on an outward-facing side of the door, and an actuation interface on an inward-facing side of the door. The shell contains a clamping mechanism configured to interface with the actuation interface such that when the door is attached to the shell and the latch is operated to secure the door to the shell, the clamping mechanism is driven to clamp the inner pod within the outer pod.

In an embodiment, the actuation interface is a socket configured to receive a corresponding projection included in the clamping mechanism. In an embodiment, the actuation interface is a projection configured to be received in a socket included in the clamping mechanism. In an embodiment, the inner pod includes one or more reticle retention features, and the clamping mechanism is configured to contact the one or more reticle retention features such the one or more reticle retention features are actuated to clamp a reticle within the inner pod.

In an embodiment, a substrate container includes an inner pod configured to contain a large format reticle. The inner pod including a cover and a baseplate. The substrate container further includes an outer pod configured to contain the inner pod. The outer pod includes a shell having an opening on a front side of the outer pod and a door. The door includes an actuation feature. The shell contains a clamping mechanism configured to interface with the actuation feature such that when the door is attached to the shell, the clamping mechanism is driven to clamp the inner pod within the outer pod.

In an embodiment, the actuation feature includes a first magnet and the clamping mechanism includes a second magnet, wherein the clamping mechanism is driven to clamp the inner pod at least in part by the interaction of the first magnet and the second magnet. In an embodiment, the actuation feature includes an actuation surface configured to contact a part of the clamping mechanism such that the clamping mechanism is driven to clamp the inner pod. In an embodiment, the clamping mechanism includes a biasing spring configured to release the clamping mechanism when the door is removed from the shell. In an embodiment, the clamping mechanism includes an arm secured by a pivot, wherein a clamping surface is provided at an end of the arm. In an embodiment, the inner pod includes one or more reticle retention features, and the clamping mechanism is configured to contact the one or more reticle retention features such the one or more reticle retention features are actuated to clamp a reticle within the inner pod.

In an embodiment, a substrate container includes an inner pod configured to contain a large format reticle. The inner pod includes a cover and a baseplate. The substrate further includes an outer pod configured to contain the inner pod. The outer pod includes a shell having an opening on a bottom side of the outer pod and a door. The outer pod includes one or more latching controls provided on a front wall of the outer pod. The door includes an inner pod support, and the shell includes one or more clamping surfaces, such that the reticle is clamped between the one or more clamping surfaces and the inner pod support when the inner pod is placed on the inner pod support, and the door is positioned to close the opening on the bottom side of the shell.

In an embodiment, the inner pod includes one or more reticle retention features, and at least one of the inner pod support and the one or more clamping surfaces are configured to contact the one or more reticle retention features such the one or more reticle retention features are actuated to clamp a reticle within the inner pod.

In an embodiment, a substrate container includes an inner pod configured to contain a large format reticle. The inner pod includes a cover and a baseplate. The substrate container further includes an outer pod configured to contain the inner pod. The outer pod includes a shell having an opening on a front side of the outer pod, the shell including a clamping mechanism. The clamping mechanism is configured such that in a resting state, the clamping mechanism is positioned to clamp the inner pod within the outer pod, and when in an actuated state, the clamping mechanism is positioned such that the inner pod can be removed from the outer pod.

In an embodiment, the clamping mechanism is configured to be placed into the actuated state by application of mechanical force at an actuation interface. In an embodiment, the actuation interface is provided on a side wall of the shell. In an embodiment, the actuation interface is provided on a bottom of the shell. In an embodiment, the actuation interface is provided on a bottom plate attached to the shell. In an embodiment, the actuation surface is provided between a bottom of the shell and a bottom plate attached to the shell.

In an embodiment, the clamping mechanism includes a shape memory material.

In an embodiment, the clamping mechanism is configured to be placed into the actuated state by application of electrical current to an actuation surface. In an embodiment, the actuation surface is electrically connected to a shape memory material. In an embodiment, the actuation surface is located on an exterior of the shell. In an embodiment, the actuation surface is located in an interior space defined by the shell.

In an embodiment, the clamping mechanism is configured to be placed into the actuated state by application of a magnetic field to an actuation surface. In an embodiment, the actuation surface includes a magnet. In an embodiment, the actuation surface is located on an exterior of the shell. In an embodiment, the actuation surface is located in an interior space defined by the shell.

In an embodiment, the inner pod includes one or more reticle retention features, and the clamping mechanism is configured to contact the one or more reticle retention features such the one or more reticle retention features are actuated to clamp a reticle within the inner pod.

In an embodiment, a substrate container includes an inner pod configured to contain a large format reticle, the inner pod including a cover and a baseplate. The substrate container further includes an outer pod configured to contain the inner pod, the outer pod including a shell and a door. The door includes a contact surface, and the shell contains an inner pod support platform connected to the shell by one or more pivots and a clamping surface. When the door is attached to the shell, the contact surface of the door contacts the inner pod support platform so as to drive the inner pod support platform to move about the one or more pivots such that the inner pod is clamped between the inner pod support platform and the clamping surface.

In an embodiment, inner pod includes one or more reticle retention features, and one or both of the inner pod support platform and the clamping surface include one or more features configured to contact the one or more reticle retention features such the one or more reticle retention features are actuated to clamp a reticle within the inner pod when the door is attached to the shell.

In an embodiment, a substrate container includes an inner pod configured to contain a large format reticle, the inner pod including a cover and a baseplate. The substrate container further includes an outer pod configured to contain the inner pod, the outer pod including a shell and a door. The door includes a ramped inner pod support. The shell includes one or more inner pod supports and a clamping surface. Each of the one or more inner pod supports includes a flat portion and a ramped portion. When the door is attached to the shell, the ramped inner pod support of the door is configured to support the inner pod and drive the inner pod along the ramped portion of the inner pod support of the shell such that the inner pod is clamped against the clamping surface.

In an embodiment, the inner pod includes one or more reticle retention features, and the clamping surface include one or more features configured to contact the one or more reticle retention features such the one or more reticle retention features are actuated to clamp a reticle within the inner pod when the door is attached to the shell.

### DRAWINGS

FIG. 1 shows a substrate container according to an embodiment.

FIG. 2 shows a substrate container according to an embodiment.

FIG. 3A shows a substrate container according to an embodiment.

FIG. 3B shows a substrate container according to an embodiment.

FIG. 3C shows a substrate container according to an embodiment.

FIG. 4 shows a substrate container according to an embodiment.

FIG. 5 shows a substrate container according to an embodiment.

FIG. 6 shows a substrate container according to an embodiment.

FIG. 7 shows a substrate container according to an embodiment.

FIG. 8 shows a substrate container according to an embodiment.

FIG. 9 shows a substrate container according to an embodiment.

FIG. 10 shows a substrate container according to an embodiment.

FIG. 11 shows a substrate container according to an embodiment.

FIG. 12 shows a substrate container according to an embodiment.

### DETAILED DESCRIPTION

This disclosure is directed to substrate containers configured to store and retain large-format reticles.

As used herein, “inner pod” refers to a pod configured to contain a reticle.

As used herein, “outer pod” refers to a pod configured to contain an inner pod.

As used herein, “large format reticle” is a reticle having an increased size beyond a nominal size of six inches by six inches. In embodiments, the large format reticle can have a generally square shape. In embodiments, the large format reticle can have a rectangular shape. In an embodiment, the rectangular shape can have an aspect ratio of between 1.5 to 1 and 2.5 to one.

As used herein, “FOUP” refers to a front-opening unified pod. In embodiments, a FOUP can be configured to interface with a load port, such as a 300 millimeter (300 mm) load port.

As used herein, “SMIF pod” refers to a standard mechanical interface pod.

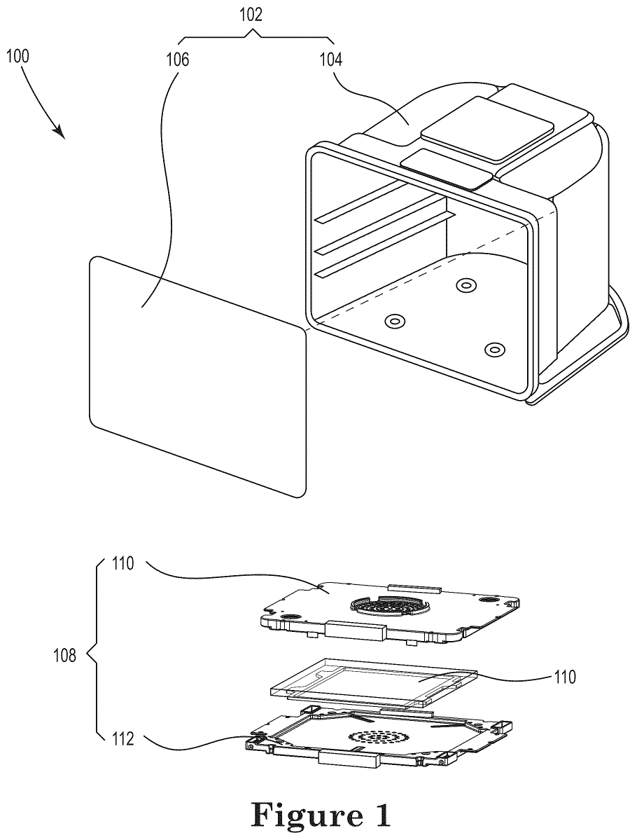

FIG. 1 shows a substrate container according to an embodiment. Substrate container 100 includes an outer pod 102 including a shell 104 and a door 106, and an inner pod 108 including a cover 110 and a baseplate 112. The inner pod 108 is configured to accommodate a large format reticle 114. Substrate container 100 is a substrate container configured to securely contain large format reticle 114 within inner pod 108, and to securely contain inner pod 108 within outer pod 102. In an embodiment, outer pod 102 is configured to interface with a standard 300 mm load port. In an embodiment, outer pod 102 is a FOUP modified to contain one or more mechanisms for retaining inner pod 108, for example according to the example embodiments provided herein. In an embodiment, outer pod 102 can be a FOUP modified to present the door on a top or bottom side as opposed to a front of the outer pod 102. Substrate container 100 can, in embodiments, be a SMIF pod being modified such that the large format reticle 114 can be contained therein. Door 106 can be used to close outer pod 102 when inner pod 108 is contained therein.

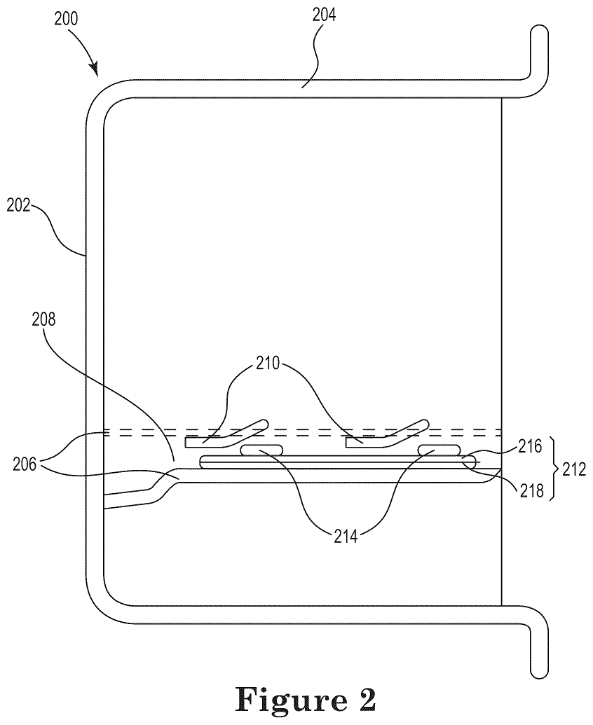

FIG. 2 shows a substrate container according to an embodiment. Substrate container 200 is shown in a sectional view. Substrate container 200 includes outer pod 202 including shell 204 and a door (not shown). The shell 204 includes flanges 206 defining a groove 208. Outer pod 202 can further include one or more securement features 210 configured to interface with inner pod 212 at reticle retention features 214. Inner pod 212 also includes cover 216, baseplate 218.

Substrate container 200 can be a modified FOUP, or any other suitable pod design. In an embodiment, substrate container 200 is capable of interface with a 300 mm load port. The substrate container 200 is configured to retain a reticle inside of inner pod 212, between cover 216 can baseplate 218. In an embodiment, reticle retention features 214 can be provided to allow the securement of the reticle within inner pod 212. As a non-limiting example, the reticle retention features 214 can be one or more vertically movable pins configured to clamp the reticle when actuated, for example by contact between the securement features 210 provided in outer pod 202 and an actuation surface provided on the reticle retention features 214.

Shell 204 includes flange 206. The flanges 206 define a groove 208 configured to receive the inner pod 212. The flanges 206 can be spaced and/or angled such that groove 208 is configured to apply a clamping force driving cover 216 and baseplate 218 together when inner pod 212 is inserted into groove 208. In an embodiment, the flanges 206 defining groove 208 are parallel to one another. In an embodiment, the flanges 206 defining groove 208 are angled with respect to one another, such that the width of groove 208 tapers down when moving from the opening of the outer pod 202 towards a back wall opposite said opening.

In an embodiment where the inner pod 212 includes reticle retention features 214, securement features 210 can further be provided in outer pod 202. The securement features 210 can, for example, be projections extending from top, side, or bottom walls of the shell 204. The securement features 210 can be configured to interface with reticle retention features 214, for example pressing against actuation surfaces on the reticle retention features 214 so as to drive movable pins, such that the movable pins apply clamping forces to secure the reticle within the inner pod 212. In an embodiment where outer pod 202 includes securement features 210, one of flanges 206 can be omitted. In such an embodiment, the remaining flange 206 can provide a shelf configured to support the inner pod 212. Downwards clamping force to secure inner pod 212 and the reticle contained therein can be provided by the contact between the securement features 210 and cover 216 in such an embodiment.

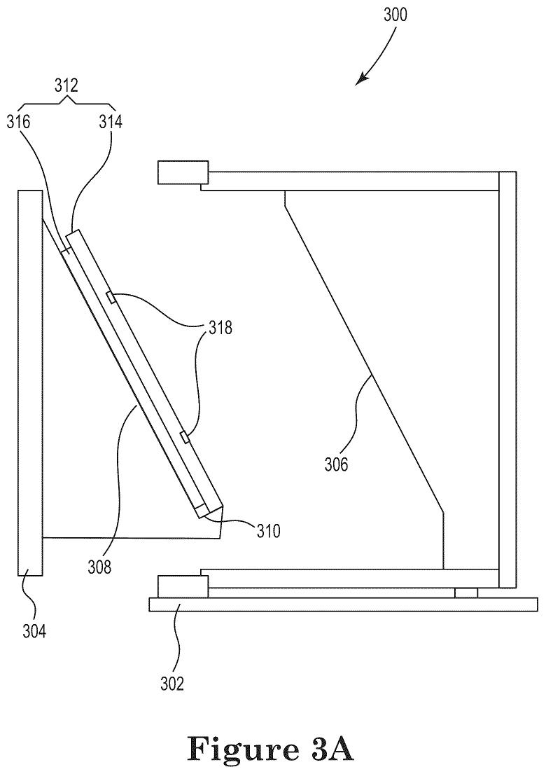

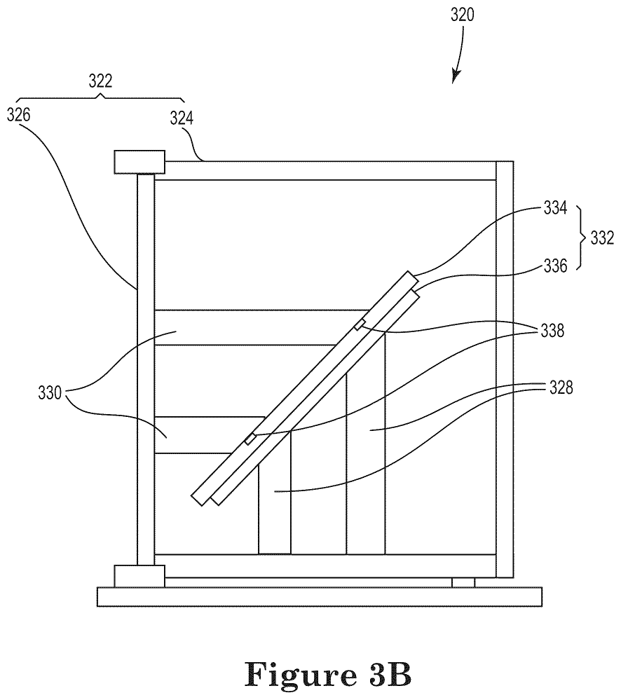

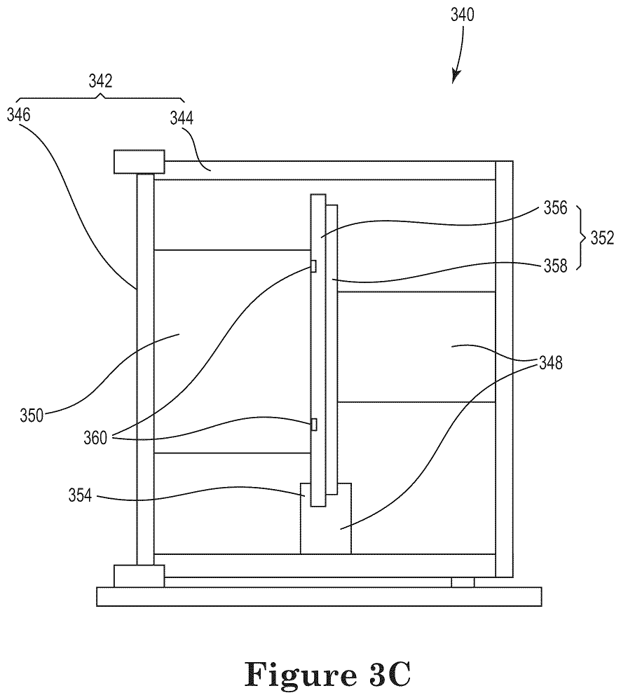

FIG. 3A shows a substrate container according to an embodiment. Substrate container 300 includes shell 302 and door 304. Shell 302 includes at least one first angled clamping surface 306. Door 304 includes at least one second angled clamping surface 308. Door 304 can further include an inner pod retainer 310. Inner pod 312 includes cover 314 and baseplate 316. The inner pod 312 can further include reticle retention features 318.

When inner pod 312 is to be stored within outer pod 302, the inner pod 312 can be placed on the second angled clamping surface 308 provided on door 304. In an embodiment, inner pod retainer 310 can maintain the relative positions of cover 314 and baseplate 316 such that the inner pod 312 remains closed even when angled due to resting on the second angled clamping surface 308. The door 304 can be joined to the shell 302, with the inner pod 312 and second angled clamping surface 308 directed into the interior space defined by the shell 302. The door 304 can be moved to a position where the door 304 and shell 302 can be latched to one another. The first angled clamping surface 306 can contact the inner pod 312 when the door 304 is positioned for latching or when the door 304 is latched. The contact of the first angled clamping surface 306 and second angled clamping surface 308 with the inner pod 312 when the shell 302 and door 304 are joined can provide clamping to hold the inner pod 312 closed while allowing the door 304 to be opened and removed in a horizontal direction. In embodiments, portions of the angled clamping surfaces 306 and/or 308 can interface with reticle retention features 318 of the inner pod 312. The reticle retention features 318 can be, for example, movable posts configured to be actuated from an exterior of the inner pod 312 and thereby moved to clamp the reticle contained within inner pod 312. The interface of portions of the angled clamping surfaces 306 and/or 308 with reticle retention features 318 can drive the reticle retention features 318 to clamp a reticle contained within inner pod 312 when the shell 302 and door 304 are joined.

FIG. 3B shows a substrate container according to an embodiment. Substrate container 320 includes outer pod 322. Outer pod 322 includes shell 324 and door 326. Shell 324 includes angled inner pod support 328. Door 326 includes angled clamping surface 330. Angled inner pod support 328 is configured to support an inner pod 332 such that the inner pod is angled with respect to a horizontal direction. When the inner pod 332 is resting on the angled inner pod support 328 and door 326 attached to shell 324, the angled clamping surface 330 can contact the inner pod 332 so as to clamp the inner pod 332 against the angled inner pod support 328. The inner pod 332 can include cover 334 and baseplate 336. The clamping of the inner pod 332 can retain the cover 334 and baseplate 336 together and maintain the position thereof. In embodiments, the inner pod 332 can further include reticle retention features 338. The reticle retention features 338 can be, for example, movable posts configured to clamp a reticle contained within inner pod 332 when actuated. The reticle retention features 338 can be actuated by respective features provided on one or both of the angled inner pod support 328 and/or the angled clamping surface 330.

FIG. 3C shows a substrate container according to an embodiment. Substrate container 340 includes outer pod 342. Outer pod 342 includes shell 344 and door 346. Shell 344 includes vertical inner pod support 348. The door 346 includes a clamping surface 350. Vertical inner pod support 348 is configured to support an inner pod 352 such that a major plane of the inner pod 352 and/or a reticle contained therein are oriented in a vertical direction. The vertical inner pod support 348 can include one or more retention features 354 to facilitate retention of the inner pod 352 in the vertical orientation, for example to prevent a cover 356 and a baseplate 358 of the inner pod 352 from separating when in the vertical orientation. When the inner pod 352 is resting on vertical inner pod support 348 and the door 346 is attached to shell 344, the clamping surface 350 can contact the inner pod 352 so as to clamp the inner pod 352 against the vertical inner pod support 348. The clamping of the inner pod 352 can retain the cover 356 and baseplate 358 together and maintain the position thereof. In embodiments, the inner pod 352 can further include reticle retention features 360. The reticle retention features 360 can be, for example, movable posts configured to clamp a reticle contained within inner pod 352 when actuated. The reticle retention features 360 can be actuated by respective features provided on one or both of the vertical inner pod support 348 and/or the clamping surface 350.

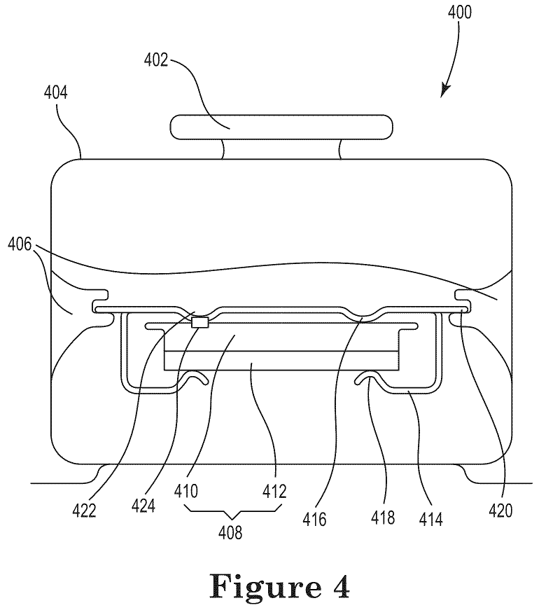

FIG. 4 shows a substrate container according to an embodiment. Substrate container 400 includes outer pod 402 including shell 404 and a door (not shown). Outer pod 402 includes supports 406. The substrate container 400 further includes an inner pod 408 including cover 410 and baseplate 412. A clip 414 is further provided.

Outer pod 402 can be defined by shell 404. One or more supports 406 can be provided in the interior space defined by shell 406. Supports 406 are configured to support the inner pod 408 within the space defined by shell 404, either directly or by way of supporting clip 414. In an embodiment, supports 406 are configured to receive one or more features of clip 414 so as to support clip 414 when inner pod 408 is held within clip 414. In an embodiment, supports 406 are one or more ledges, flanges, posts, pillars, or any other such suitable feature capable of directly supporting the inner pod 408.

Inner pod 408 includes cover 410 and baseplate 412, which are configured to contain a large format reticle. The cover 410 and baseplate 412 can be clamped together by way of one or more clips 414. Clip 414 includes at least one cover contact surface 416 and at least one baseplate contact surface 418. The clip 414 is configured such that cover contact surface 416 and baseplate contact surface 418 oppose one another and are spaced apart such that the clip 414 can provide clamping force retaining cover 410 and baseplate 412 together. The clip 414 can be made of any suitable material capable of deformation to be placed on cover 410 and baseplate 412 while having sufficient resilience to apply the clamping force. As non-limiting examples, the clip 414 can be a metal material such as any suitable spring steel, or a polymer material. Clip 414 can optionally include additional features, such as, for example, flanges 420 configured to be received in slots provided as the one or more supports 406 of outer pod 402. In an embodiment, the additional features can include actuation surfaces 422 for reticle retainers 424 provided on inner pod 408. The reticle retainers 424 can be, as a non-limiting example, movable pins configured to apply clamping force the reticle within inner pod 408, and the actuation surfaces 422 can be portions of clip 414 configured to contact the reticle retainers 424 so as to push the movable pins inwards with respect to inner pod 408 such that said clamping force is applied.

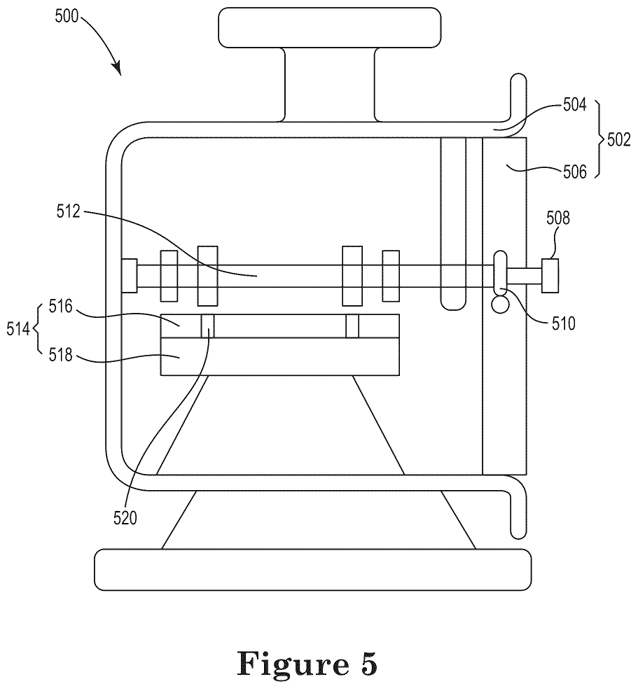

FIG. 5 shows a substrate container according to an embodiment. Substrate container 500 includes outer pod 502 including shell 504 and door 506. Door 506 includes latch operation interfaces 508 on an exterior-facing side of door 506 and actuation interfaces 510 on an interior-facing side of door 506. The outer pod 502 includes one or more retention elements 512 configured to be actuated by rotation transferred by the actuation interfaces 510. The substrate container 500 further includes inner pod 514 including cover 516, baseplate 518, and reticle retention features 520.

Substrate container 500 is configured such that operation of the latch for door 506 by way of latch operation interfaces 508 also provides clamping of the cover 516 to baseplate 518 when the door 506 is latched to shell 504. The latch operation interfaces 508 can be any suitable interfaces capable of being operated by automation at a load port, such as a projection, a handle, a socket, or the like. The latch operation interfaces 508 are each configured to provide force to operate the latch of door 506 and further to provide force to one or more respective actuation interfaces 510. In an embodiment, one or more cams, gears, or other suitable mechanical connections can be used in the transference of force from latch operation interfaces 508 to the respective actuation interfaces 510. In an embodiment, the latch operation interfaces 508 can be directly connected to actuation interfaces 510, such that rotation of the latch operation interface 508 rotates the respective actuation interface 510. The one or more retention elements 512 each include a portion configured to interface with a respective actuation interface 510. The actuation interface 510 can transfer force to the respective retention element 512 so as to drive the retention element 512 from a release position to a clamping position and vice versa. The retention element 512 can be configured to be in the release position when the door 506 is unlatched from the shell 504, and driven into the clamping position when the door 506 is latched to the shell 504. As a non-limiting embodiment, the retention element 512 can include a projection configured to be received in a socket provided in the respective actuation interface 510, and an elliptical contact member having a major axis configured such that the contact member contacts the inner pod when the latch operation interface 508 is operated to latch the door 506 to shell 504, and a minor axis configured such that the contact member does not contact the inner pod when the latch operation interface 508 is operated to unlatch the door 506 from shell 504. It is understood that any suitable mechanical connections or combinations thereof, such as gears, cams, lever arms, movable elements, and the like can instead be used to provide one of the one or more retention elements 512, so long as the retention element 512 can be suitably driven between clamping and release positions by the force transferred by the respective actuation interface 510. In an embodiment, at least some of the retention elements 512 can include features configured to interface with reticle retention features 520 optionally provided on inner pod 514, such that the reticle retention features, such as movable posts, are actuated to clamp a reticle contained within inner pod 514 and thereby secure the reticle within inner pod 514.

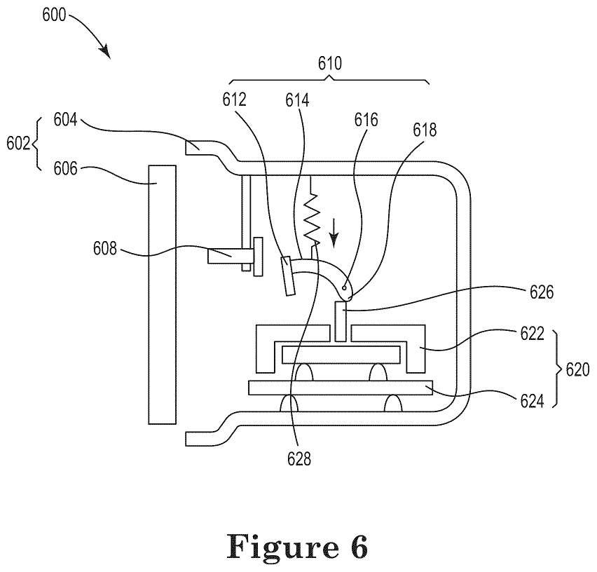

FIG. 6 shows a substrate container according to an embodiment. Substrate container 600 includes outer pod 602 including shell 604 and door 606. Door 606 or shell 604 can include an actuator 608. Shell 604 includes inner pod retainer 610. Inner pod retainer 610 includes actuator interface 612, arm 614, pivot 616, and inner pod contact 618. The substrate container 600 further includes inner pod 620. Inner pod 620 includes cover 622, baseplate 624, and reticle retention features 626.

Substrate container 600 is configured such that the positioning of door 606 in an opening provided on shell 604 drives the inner pod retainer 610 to clamp the inner pod 620 in place within the outer pod 602. The door 606 or the shell 604 can include actuator 608. Actuator 608 is configured to act on the actuator interface 612 of inner pod retainer 610 to drive the inner pod retainer 610 into a clamping position. In an embodiment, actuator 608 is a mechanical actuator such as a contact point or contact surface provided on an inside of door 606, configured to make direct physical contact with actuator interface 612. In an embodiment, actuator 608 is a magnetic actuator configured to apply magnetic force to the actuation surface 612, for example by way of a magnet included in the actuator 608. In an embodiment, actuator 608 is a magnet provided at an end of a plunger attached to shell 604, with the plunger movable by way of contact with door 606. The inner pod retainer 610 can be any mechanical arrangement configured to be driven by actuator 608 such that inner pod contact 618 contacts inner pod 620 when the door 606 is positioned at the opening provided on shell 604. As a non-limiting embodiment, the inner pod retainer 610 can include an arm 614 mounted on a pivot 616, with actuator interface 612 disposed at a first end of arm 614 and inner pod contact 618 disposed at a second end of arm 614 opposite the first end. When actuator 608 acts on actuator interface 612, arm 614 can be driven to rotate about pivot 616 such that inner pod contact 618 is brought into contact with the inner pod 620, thereby clamping inner pod 620 against support features provided in shell 604. The inner pod contact 618 can include a single contact point or a plurality of contact points connected by one or more beams. In an embodiment including a plurality of contact points, the contact points can be positioned such that the contact between inner pod contact 618 and inner pod 620 is distributed across a surface of inner pod 620. In an embodiment, a plurality of inner pod retainers 610 can be provided, with one or more of the plurality of inner pod retainers 610 being driven by a respective actuator 608 included in door 606. In such an embodiment, a plurality of actuators 608 can be provided on door 606. In an embodiment, the arm 614 and connected features can be configured such that gravity causes arm 614 to rotate about pivot 616 to move to a release state when actuator 608 is not present at or near actuator interface 612. In an embodiment, a biasing spring 628 can optionally be provided to at least assist arm 614 in rotating about pivot 616 to move to a release state when actuator 608 is not present at or near actuator interface 612. In an embodiment, inner pod 620 includes reticle retention features 626, such as movable posts configured to be driven to clamp a reticle contained within inner pod 620. In an embodiment, inner pod contact 618 can include one or more features configured to interface with one or more reticle retention features 626 such that the reticle features 626 clamp the reticle contained within inner pod 620 when the inner pod retainer 610 is in a clamping position.

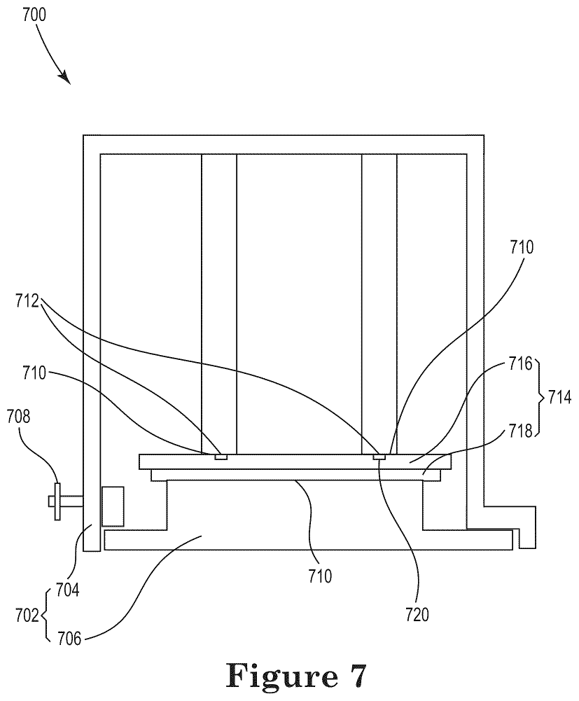

FIG. 7 shows a substrate container according to an embodiment. Substrate container 700 includes outer pod 702 having a shell 704 and a bottom-side door 706. The outer pod 702 includes front-mounted latch interfaces 708. Inner pod clamping surfaces 710 and reticle retention actuators 712 can be included in outer pod 702, for example in one or both of shell 704 and bottom-side door 706. Substrate container 700 further includes inner pod 714. Inner pod 714 includes cover 716, baseplate 718, and reticle retention features 720.

The outer pod 702 is configured such that shell 704 and door 706 can be separated by vertical movement of one or both of shell 704 and door 706 when the door 706 is separated from the shell. The inner pod clamping surfaces 710 can be configured such that the cover 716 and baseplate 718 of inner pod 714 are clamped together when the door 706 is secured to the shell 704. Substrate container 700 is configured to be opened vertically, such that the cover 716 and baseplate 718 of the inner pod 714 can remain aligned and retained together by gravity during opening and closing of the outer pod 702. The front-mounted latch interfaces 708 are provided on a front of the shell 704 configured to engage with a load port. The front-mounted latch interfaces 708 are configured to be engaged by automation at the load port such that the latch is operated to secure or release door 706 from shell 704. Front-mounted latch interfaces 708 can be any suitable interfaces for load port automation, such as projections configured to be engaged and rotated, sockets configured to receive a projection from the automation, and the like. The front-mounted latch interfaces 708 are configured to transfer the force provided by the load port automation at a front of the shell 704 to operate a latch configured to retain or release the bottom-facing door 706. The automation provided at the load port can include automation suitable for use with FOUPs and the manipulation of door latches for a FOUP.

Inner pod 714 can optionally include reticle retention features 720 to clamp the reticle within the inner pod 714. The reticle retention features 720 can be, as a non-limiting example, movable posts that can be driven by contact with reticle retention actuators 712 to contact the reticle, thereby clamping the reticle such that the reticle is secured within inner pod 714. The reticle retention actuators 712 can be projections provided at suitable positions and heights to actuate the reticle retention features 720 such that the reticle retention features 720 clamp the reticle when the door 706 is secured to shell 704.

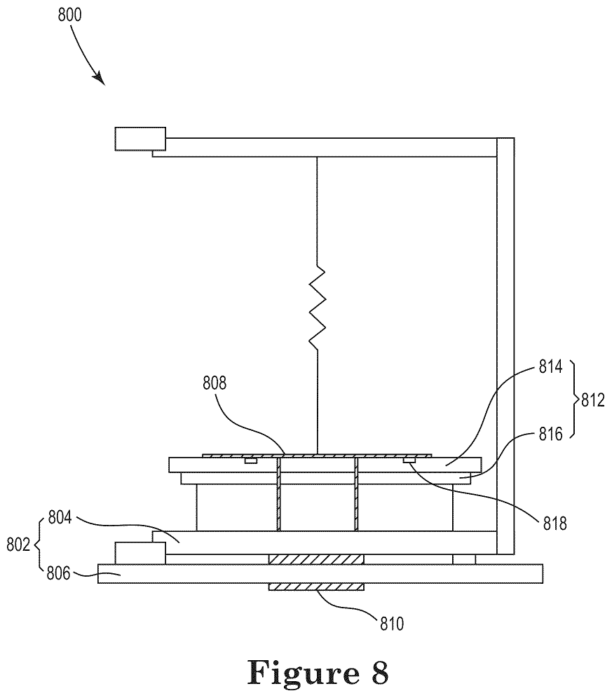

FIG. 8 shows a substrate container according to an embodiment. Substrate container 800 includes outer pod 802 including shell 804, a door (not shown), and a bottom plate 806. An inner pod retainer 808 is provided in outer pod 802. An actuator interface 810 is provided, connected to inner pod retainer 808. Substrate container 800 further includes inner pod 812. Inner pod 812 includes cover 814, baseplate 816, and reticle retention features 818. Outer pod 802 can be any suitable pod for containing inner pod 812. In an embodiment, outer pod 802 is a FOUP or a modified FOUP. In an embodiment, outer pod 802 is configured to be compatible with a load port, such as a 300 mm load port. Inner pod retainer 808 is configured to clamp cover 814 and baseplate 816 of inner pod 812 together when in a non-actuated state, for example by using spring force to drive one or more retention elements contacting at least one of cover 814 and baseplate 816. In an embodiment, a spring providing the spring force can extend from a ceiling of the interior space defined by shell 804. In an embodiment, the spring providing the spring force can be connected to a spring support provided within the interior space defined by shell 804. The inner pod retainer 808 can be moved to an actuated state by application of mechanical force at the actuator interface 810. In the actuated state, the inner pod retainer 808 can release the inner pod 812, such that inner pod 812 can be removed from outer pod 802. The actuator interface 810 can be physically connected to inner pod retainer 808, for example through any suitable combination of mechanical features such as plungers, contact surfaces, lever arms, and the like, such that force applied to the actuator interface 810 is transferred to inner pod retainer 808 so as to move inner pod retainer 808 into the actuated state where inner pod 812 is released. Actuator interface can be contacted by a projection or other suitable interaction feature provided on a tool used with substrate container 800 such as a tool configured to manipulate the inner pod 812. In an embodiment, actuator interface 810 is provided on bottom plate 806. In an embodiment, the actuator interface 810 can be provided at a retaining feature on the bottom plate 806, for example at a standard front retaining feature, a standard center retaining feature, or the like. In an embodiment, actuator interface is provided between bottom plate 806 and shell 804. In an embodiment, actuator interface 810 is provided on shell 804. In an embodiment, actuator interface 810 is provided on a top, side, or back wall of shell 804. In an embodiment, actuator interface 810 is provided on a bottom wall of shell 804 and is accessible through an opening provided in bottom plate 806. In an embodiment, the inner pod retainer 808 can return to the non-actuated state, clamping the inner pod 812 and thereby securely retaining the inner pod 812 when force is no longer being applied at actuator interface 810, or when such force is below a threshold force. In an embodiment, the inner pod retainer 808 can be returned to the clamped state by another operation performed by the tool, following placement of the inner pod 812 within outer shell 802, for example by mechanical, electrical, or magnetic manipulation. In an embodiment, one or more features of inner pod retainer 808 can be configured to interface with one or more reticle retention features 818 provided on inner pod 812. The reticle retention features 818 can be configured to apply a clamping force to a reticle contained within inner pod 812, for example by being movable posts capable of being driven to clamp the reticle when interfaced with. The interfacing of inner pod retainer 808 with the one or more reticle retention features 818 can occur when the inner pod retainer 808 is in the non-actuated position where inner pod retainer 808 clamps the inner pod 812. The interfacing of inner pod retainer 808 with the one or more reticle retention features 818 can drive the reticle retention features 818 to apply the clamping force to the reticle.

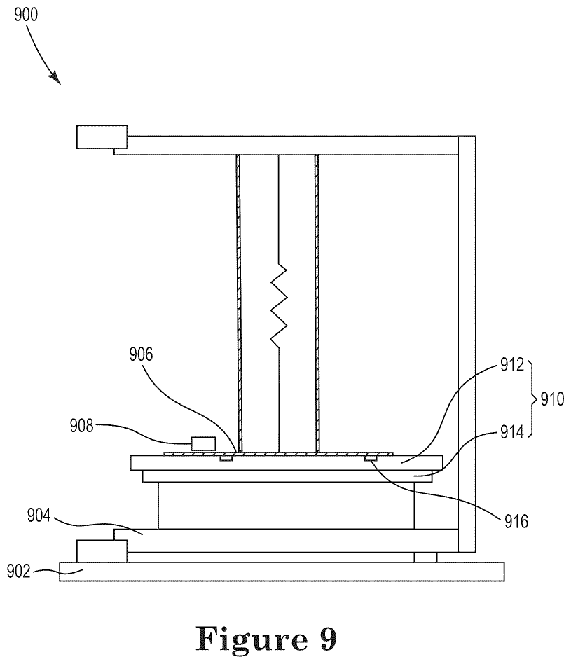

FIG. 9 shows a substrate container according to an embodiment. Substrate container 900 includes outer pod 902 including shell 904, a door (not shown), and inner pod retainer 906. The inner pod retainer 906 can include a magnetic actuation interface 908. Substrate container 900 includes inner pod 910. Inner pod 910 includes cover 912, baseplate 914, and reticle retention features 916. Outer pod 902 can be any suitable pod for containing inner pod 910. In an embodiment, outer pod 902 is a FOUP or a modified FOUP. In an embodiment, outer pod 902 is configured to be compatible with a load port, such as a 300 mm load port. Inner pod retainer 906 is configured to clamp cover 912 and baseplate 914 of inner pod 910 together when in a non-actuated state, for example by using spring force to drive one or more retention elements contacting at least one of cover 912 and baseplate 914. In an embodiment, a spring providing the spring force can extend from a ceiling of the interior space defined by shell 904. In an embodiment, the spring providing the spring force can be connected to a spring support provided within the interior space defined by shell 904. The inner pod retainer 906 can be moved to an actuated state by application of magnetic force at the magnetic actuation interface 908. In the actuated state, the inner pod retainer 906 can release the inner pod 910, such that inner pod 910 can be removed from outer pod 902. In an embodiment, the actuation of inner pod retainer 906 can be performed through use of a magnet being used to repel another magnet that is provided in the magnetic actuation interface 908. Magnetic actuation interface 908 can be configured to be operated by a tool, such as a tool configured to handle inner pod 910 when the door is removed and a portion of the tool extends into the internal space defined by shell 904. The magnetic actuation interface 908 can include a magnet that is repelled by another magnet provided on the tool, thereby driving the inner pod retainer 906 into the actuated state, releasing inner pod 910. In an embodiment, the inner pod retainer 906 can return to the non-actuated state, clamping the inner pod 910 and thereby securely retaining the inner pod 910 when the magnet on the tool is no longer in proximity to magnetic actuation interface 908. In an embodiment, the inner pod retainer 906 can be returned to the clamped state by another operation performed by the tool, following placement of the inner pod 910 within outer shell 902, for example by mechanical, electrical, and/or magnetic manipulation. In an embodiment, one or more features of inner pod retainer 906 can be configured to interface with one or more reticle retention features 916 provided on inner pod 910. The reticle retention features 916 can be configured to apply a clamping force to a reticle contained within inner pod 910, for example by being movable posts capable of being driven to clamp the reticle when interfaced with. The interfacing of inner pod retainer 906 with the one or more reticle retention features 916 can occur when the inner pod retainer 906 is in the non-actuated position where inner pod retainer 906 clamps the inner pod 910. The interfacing of inner pod retainer 906 with the one or more reticle retention features 916 can drive the reticle retention features 916 to apply the clamping force to the reticle.

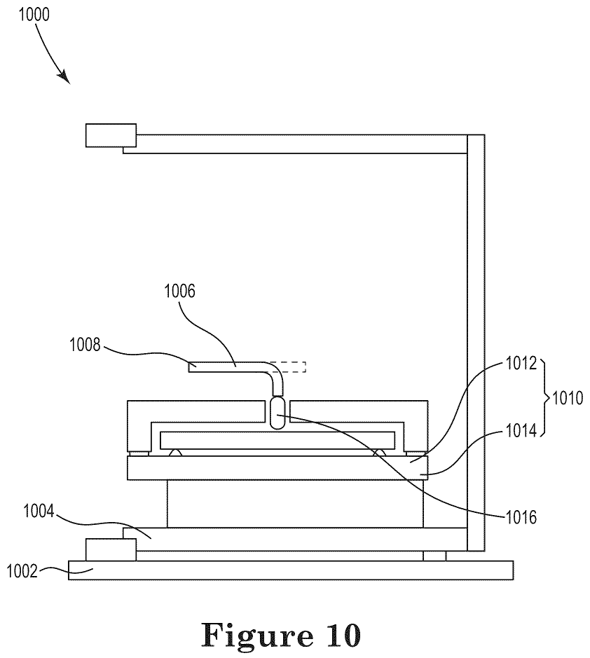

FIG. 10 shows a substrate container according to an embodiment. Substrate container 1000 includes outer pod 1002 including shell 1004, a door (not shown), and inner pod retainer 1006. The inner pod retainer 1006 can include an electrical actuation interface 1008. Substrate container 1000 includes inner pod 1010. Inner pod 1010 includes cover 1012, baseplate 1014, and reticle retention features 1016. Outer pod 1002 can be any suitable pod for containing inner pod 1010. In an embodiment, outer pod 1002 is a FOUP or a modified FOUP. In an embodiment, outer pod 1002 is configured to be compatible with a load port, such as a 300 mm load port. Inner pod retainer 1006 is configured to clamp cover 1012 and baseplate 1014 of inner pod 1010 together when in a non-actuated state, for example by using spring force to drive one or more retention elements contacting at least one of cover 1012 and baseplate 1014. In an embodiment, a spring providing the spring force can extend from a ceiling of the interior space defined by shell 1004. In an embodiment, the spring providing the spring force can be connected to a spring support provided within the interior space defined by shell 1004. The inner pod retainer 1006 can be moved to an actuated state by application of electrical current at the electrical actuation interface 1008. In the actuated state, the inner pod retainer 1006 can release the inner pod 1010, such that inner pod 1010 can be removed from outer pod 1002. In an embodiment, the actuation of inner pod retainer 1006 can be performed through use of an electrically powered actuator, operated by the application of electrical current at electrical actuation interface 1008. In an embodiment, inner pod retainer 1006 can include at least one element of a shape memory material configured to move to an actuated state (shown in broken lines) when current is supplied at electrical actuation interface 1008. Electrical actuation interface 1008 can be configured to be contacted by a tool, such as a tool configured to handle inner pod 1010 when the door is removed and a portion of the tool extends into the internal space defined by shell 1004. The electrical actuation interface 1008 can include contacts where the tool can supply electricity, thereby driving the inner pod retainer 1006 into the actuated state, releasing inner pod 1010. In an embodiment, the inner pod retainer 1006 can return to the non-actuated state, clamping the inner pod 1010 and thereby securely retaining the inner pod 1010 when electricity is not being provided or when the supplied voltage and/or current fall below a threshold value. In an embodiment, the inner pod retainer 1006 can be returned to the clamped state by another operation performed by the tool, following placement of the inner pod 1010 within outer shell 1002, for example by mechanical, electrical, or magnetic manipulation. In an embodiment, one or more features of inner pod retainer 1006 can be configured to interface with one or more reticle retention features 1016 provided on inner pod 1010. The reticle retention features 1016 can be configured to apply a clamping force to a reticle contained within inner pod 1010, for example by being movable posts capable of being driven to clamp the reticle when interfaced with. The interfacing of inner pod retainer 1006 with the one or more reticle retention features 1016 can occur when the inner pod retainer 1006 is in the non-actuated position where inner pod retainer 1006 clamps the inner pod 1010. The interfacing of inner pod retainer 1006 with the one or more reticle retention features 1016 can drive the reticle retention features 1016 to apply the clamping force to the reticle.

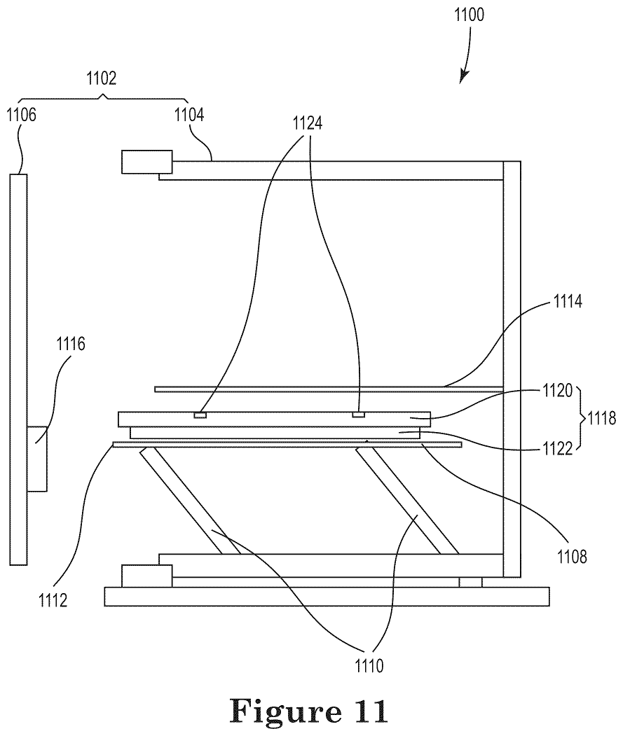

FIG. 11 shows a substrate container according to an embodiment. Substrate container 1100 includes outer pod 1102. Outer pod 1102 includes shell 1104 and door 1106. The shell 1104 includes an inner pod support platform 1108 supported by one or more pivots 1110. The inner pod support platform 1108 further includes a door contact 1112. Shell 1104 further includes one or more clamping surfaces 1114 positioned above the inner pod support platform 1108. The door 1106 includes a contact surface 1116, configured to contact the inner pod support platform 1108. Inner pod 1118 is configured to be placed on inner pod support platform 1108. The inner pod 1118 includes cover 1120 and baseplate 1122. The inner pod 1118 can further include reticle retention features 1124, such as movable posts, configured to clamp a reticle within the inner pod 1118 when reticle retention features 1124 are actuated. When inner pod 1118 is resting on inner pod support platform 1108 and door 1106 is attached to shell 1104, the door contact 1112 can be contacted by contact surface 1116 provided on door 1106, thereby driving the inner pod support platform 1108 to rotate about the one or more pivots 1110, thereby raising the inner pod support platform 1108 such that inner pod 1118 is clamped between inner pod support platform 1108 and the one or more clamping surfaces 1114. In an embodiment, at least one of inner pod support platform 1108 and the one or more clamping surfaces 1114 can include one or more features configured to interface with the reticle retention features 1124 so as to actuate reticle retention features 1124 to clamp a reticle within the inner pod 1118.

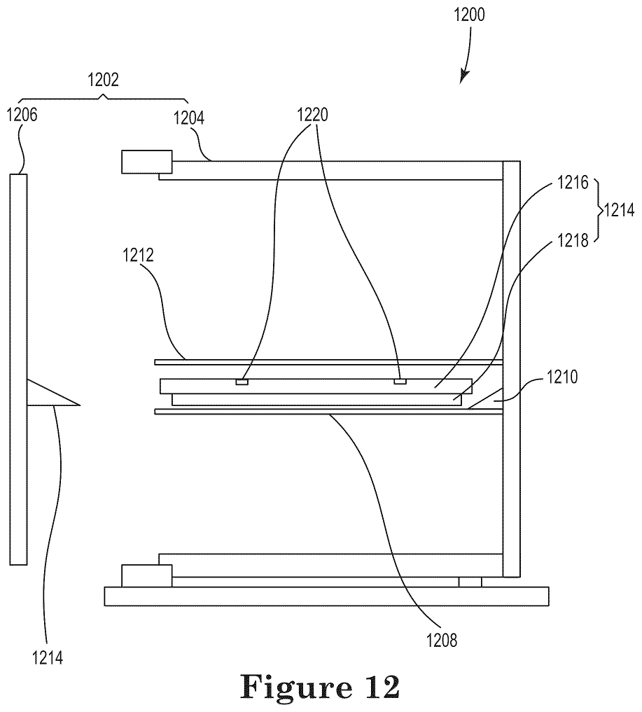

FIG. 12 shows a substrate container according to an embodiment. Substrate container 1200 includes outer pod 1202. Outer pod 1202 includes shell 1204 and door 1206. Shell 1204 includes one or more inner pod supports 1208 each including a ramped portion 1210. The shell 1204 further includes one or more inner pod clamping surfaces 1212. The door 1206 includes a ramped inner pod support 1214. The substrate container 1200 further includes inner pod 1216, which includes cover 1218 and baseplate 1220. The inner pod 1216 can further include one or more reticle retention features 1222. The inner pod supports 1208 can be a shelf, platform, or one or more flanges extending from shell 1204 configured to support inner pod 1216 within the interior space defined by shell 1204. The inner pod support 1208 and the inner pod clamping surface 1212 can be spaced apart such that the inner pod 1216 can rest on a flat portion of the inner pod support 1208 without contacting the inner pod clamping surface 1212, and can be readily placed into or removed from the substrate container 1200. When the inner pod 1216 is placed on the inner pod support 1208 and the door 1206 is attached to shell 1204, the ramped inner pod support 1214 can push the inner pod 1216 backwards to ride up the ramped portion 1210, thereby lifting the inner pod 1216 on ramped portion 1210 and ramped inner pod support 1214 such that inner pod 1216 is clamped against the inner pod clamping surface(s) 1212. In an embodiment, the shell 1204 can contain one or more features configured to actuate the one or more reticle retention features 1222 to clamp a reticle contained within inner pod 1216 when the door 1206 is attached to shell 1204.

### ASPECTS

Aspect 1. A substrate container, comprising:
an inner pod configured to contain a large format reticle, the inner pod including a cover and a baseplate; and
an outer pod configured to contain the inner pod, the outer pod having an opening on a front side of the outer pod, the outer pod including first flanges on opposing side walls, the first flanges configured to support the inner pod.

Aspect 2. The substrate container according to aspect 1, wherein the outer pod includes second flanges on said opposing side walls, the respective first flanges and second flanges on each respective side wall defining a groove configured to receive the inner pod such that the cover and the baseplate are clamped.

Aspect 3. The substrate container according to aspect 2, wherein the respective first flanges and second flanges are angled with respect to one another.

Aspect 4. The substrate container according to any of aspects 1-3, wherein the inner pod includes one or more reticle retention features, and the outer pod includes one or more securement features configured to, when the inner pod is inserted into the outer pod, actuate the reticle retention features such that a reticle is clamped within the inner pod.

Aspect 5. A substrate container, comprising:
an inner pod configured to contain a large format reticle, the inner pod including a cover and a baseplate; and
an outer pod configured to contain the inner pod, the outer pod including a shell having an opening on a front side of the outer pod and a door configured to be secured so as to cover the opening, the shell including a first angled clamping surface and the door including a second angled clamping surface, wherein the first angled clamping surface and the second angled clamping surface are configured to clamp the cover and the baseplate when the door is secured to the shell, wherein the first angled clamping surface and the second angled clamping surface are configured to support the inner pod when the inner pod is oriented vertically or oriented at an angle to a horizontal direction.

Aspect 6. The substrate container according to aspect 5, wherein one of the first clamping surface or the second clamping surface further comprises an inner pod retainer configured to maintain an alignment of the cover and the baseplate when the inner pod rests on the second angled clamping surface.

Aspect 7. The substrate container according to any of aspects 5-6, wherein the inner pod includes one or more reticle retention features, and at least one of the first angled clamping surface and the second angled clamping surface is configured to interface with at least some of the one or more reticle retention features such that said at least some of the one or more reticle retention features are actuated to clamp a reticle within the inner pod.

Aspect 8. A substrate container, comprising:
an inner pod configured to contain a large format reticle, the inner pod including a cover and a baseplate;
an outer pod configured to contain the inner pod, the outer pod including a shell having an opening on a front side of the outer pod; and
a clip configured to be attached to the inner pod such that the clip clamps the cover to the baseplate.

Aspect 9. The substrate container according to aspect 8, wherein the outer pod includes one or more supports configured to receive one or more portions of the clip such that the clip is supported when the clip is attached to the inner pod and the inner pod is inserted into the outer pod.

Aspect 10. The substrate container according to aspect 8, wherein the outer pod includes one or more supports configured to contact the inner pod such that the inner pod is supported by contact with the supports when the clip is attached to the inner pod and the inner pod is inserted into the outer pod.

Aspect 11. The substrate container according to any of aspects 8-10, wherein the inner pod includes one or more reticle retention features, and the clip is configured to contact the one or more reticle retention features such the one or more reticle retention features are actuated to clamp a reticle within the inner pod.

Aspect 12. A substrate container, comprising:
an inner pod configured to contain a large format reticle, the inner pod including a cover and a baseplate; and
an outer pod configured to contain the inner pod, the outer pod including a shell having an opening on a front side of the outer pod and a door,
wherein the door includes a latch, a latch interface on an outward-facing side of the door, and an actuation interface on an inward-facing side of the door, and
wherein the shell contains a clamping mechanism configured to interface with the actuation interface such that when the door is attached to the shell and the latch is operated to secure the door to the shell, the clamping mechanism is driven to clamp the inner pod within the outer pod.

Aspect 13. The substrate container according to aspect 12, wherein the actuation interface is a socket configured to receive a corresponding projection included in the clamping mechanism.

Aspect 14. The substrate container according to aspect 12, wherein the actuation interface is a projection configured to be received in a socket included in the clamping mechanism.

Aspect 15. The substrate container according to any of aspects 12-14, wherein the inner pod includes one or more reticle retention features, and the clamping mechanism is configured to contact the one or more reticle retention features such the one or more reticle retention features are actuated to clamp a reticle within the inner pod.

Aspect 16. A substrate container, comprising:
an inner pod configured to contain a large format reticle, the inner pod including a cover and a baseplate;
an outer pod configured to contain the inner pod, the outer pod including a shell having an opening on a front side of the outer pod and a door,
wherein the door includes an actuation feature, and
wherein the shell contains a clamping mechanism configured to interface with the actuation feature such that when the door is attached to the shell, the clamping mechanism is driven to clamp the inner pod within the outer pod.

Aspect 17. The substrate container according to aspect 16, wherein the actuation feature includes a first magnet and the clamping mechanism includes a second magnet, wherein the clamping mechanism is driven to clamp the inner pod at least in part by the interaction of the first magnet and the second magnet.

Aspect 18. The substrate container according to any of aspects 16-17, wherein the actuation feature includes an actuation surface configured to contact a part of the clamping mechanism such that the clamping mechanism is driven to clamp the inner pod.

Aspect 19. The substrate container according to any of aspects 16-18, wherein the clamping mechanism includes a biasing spring configured to release the clamping mechanism when the door is removed from the shell.

Aspect 20. The substrate container according to any of aspects 16-19, wherein the clamping mechanism includes an arm secured by a pivot, wherein a clamping surface is provided at an end of the arm.

Aspect 21. The substrate container according to any of aspects 16-20, wherein the inner pod includes one or more reticle retention features, and the clamping mechanism is configured to contact the one or more reticle retention features such the one or more reticle retention features are actuated to clamp a reticle within the inner pod.

Aspect 22. A substrate container, comprising:
an inner pod configured to contain a large format reticle, the inner pod including a cover and a baseplate;
an outer pod configured to contain the inner pod, the outer pod including a shell having an opening on a bottom side of the outer pod and a door, wherein the outer pod includes one or more latching controls provided on a front wall of the outer pod,
wherein the door includes an inner pod support, and the shell includes one or more clamping surfaces, such that the reticle is clamped between the one or more clamping surfaces and the inner pod support when the inner pod is placed on the inner pod support, and the door is positioned to close the opening on the bottom side of the shell.

Aspect 23. The substrate container according to aspect 22, wherein the inner pod includes one or more reticle retention features, and at least one of the inner pod support and the one or more clamping surfaces are configured to contact the one or more reticle retention features such the one or more reticle retention features are actuated to clamp a reticle within the inner pod.

Aspect 24. A substrate container, comprising:
an inner pod configured to contain a large format reticle, the inner pod including a cover and a baseplate;
an outer pod configured to contain the inner pod, the outer pod including a shell having an opening on a front side of the outer pod, the shell including a clamping mechanism, the clamping mechanism configured such that in a resting state, the clamping mechanism is positioned to clamp the inner pod within the outer pod, and when in an actuated state, the clamping mechanism is positioned such that the inner pod can be removed from the outer pod.

Aspect 25. The substrate container according to aspect 24, wherein the clamping mechanism is configured to be placed into the actuated state by application of mechanical force at an actuation interface.

Aspect 26. The substrate container according to aspect 25, wherein the actuation interface is provided on a side wall of the shell.

Aspect 27. The substrate container according to aspect 25, wherein the actuation interface is provided on a bottom of the shell.

Aspect 28. The substrate container according to aspect 25, wherein the actuation interface is provided on a bottom plate attached to the shell.

Aspect 29. The substrate container according to aspect 25, wherein the actuation surface is provided between a bottom of the shell and a bottom plate attached to the shell.

Aspect 30. The substrate container according to any of aspects 24-29, wherein the clamping mechanism includes a shape memory material.

Aspect 31. The substrate container according to aspect 24, wherein the clamping mechanism is configured to be placed into the actuated state by application of electrical current to an actuation surface.

Aspect 32. The substrate container according to aspect 31, wherein the actuation surface is electrically connected to a shape memory material.

Aspect 33. The substrate container according to any of aspects 31-32, wherein the actuation surface is located on an exterior of the shell.

Aspect 34. The substrate container according to any of aspects 31-32, wherein the actuation surface is located in an interior space defined by the shell.

Aspect 35. The substrate container according to aspect 24, wherein the clamping mechanism is configured to be placed into the actuated state by application of a magnetic field to an actuation surface.

Aspect 36. The substrate container according to aspect 35, wherein the actuation surface includes a magnet.

Aspect 37. The substrate container according to any of aspects 35-36, wherein the actuation surface is located on an exterior of the shell.

Aspect 38. The substrate container according to any of aspects 35-36, wherein the actuation surface is located in an interior space defined by the shell.

Aspect 39. The substrate container according to any of aspects 24-38, wherein the inner pod includes one or more reticle retention features, and the clamping mechanism is configured to contact the one or more reticle retention features such the one or more reticle retention features are actuated to clamp a reticle within the inner pod.

Aspect 40. A substrate container, comprising:
an inner pod configured to contain a large format reticle, the inner pod including a cover and a baseplate;
an outer pod configured to contain the inner pod, the outer pod including a shell and a door,
wherein the door includes a contact surface, and
wherein the shell contains an inner pod support platform connected to the shell by one or more pivots and a clamping surface,
wherein when the door is attached to the shell, the contact surface of the door contacts the inner pod support platform so as to drive the inner pod support platform to move about the one or more pivots such that the inner pod is clamped between the inner pod support platform and the clamping surface.

Aspect 41. The substrate container according to aspect 40, wherein the inner pod includes one or more reticle retention features, and one or both of the inner pod support platform and the clamping surface include one or more features configured to contact the one or more reticle retention features such the one or more reticle retention features are actuated to clamp a reticle within the inner pod when the door is attached to the shell.

Aspect 42. A substrate container, comprising:
an inner pod configured to contain a large format reticle, the inner pod including a cover and a baseplate;
an outer pod configured to contain the inner pod, the outer pod including a shell and a door,
wherein the door includes a ramped inner pod support, and
wherein the shell includes one or more inner pod supports and a clamping surface, each of the one or more inner pod supports including a flat portion and a ramped portion,
wherein when the door is attached to the shell, the ramped inner pod support of the door is configured to support the inner pod and drive the inner pod along the ramped portion of the inner pod support of the shell such that the inner pod is clamped against the clamping surface.

Aspect 43. The substrate container according to aspect 42, wherein the inner pod includes one or more reticle retention features, and the clamping surface include one or more features configured to contact the one or more reticle retention features such the one or more reticle retention features are actuated to clamp a reticle within the inner pod when the door is attached to the shell.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

What is claims is:

1-11. (canceled)

12. A substrate container, comprising:
an inner pod configured to contain a large format reticle, the inner pod including a cover and a baseplate; and
an outer pod configured to contain the inner pod, the outer pod including a shell having an opening on a front side of the outer pod and a door,
wherein the door includes a latch, a latch interface on an outward-facing side of the door, and an actuation interface on an inward-facing side of the door, and
wherein the shell contains a clamping mechanism configured to interface with the actuation interface such that when the door is attached to the shell and the latch is operated to secure the door to the shell, the clamping mechanism is driven to clamp the inner pod within the outer pod.

13. The substrate container of claim 12, wherein the actuation interface is a socket configured to receive a corresponding projection included in the clamping mechanism.

14. The substrate container of claim 12, wherein the actuation interface is a projection configured to be received in a socket included in the clamping mechanism.

15. The substrate container of claim 12, wherein the inner pod includes one or more reticle retention features, and the clamping mechanism is configured to contact the one or more reticle retention features such the one or more reticle retention features are actuated to clamp a reticle within the inner pod.

16. A substrate container, comprising:
an inner pod configured to contain a large format reticle, the inner pod including a cover and a baseplate;
an outer pod configured to contain the inner pod, the outer pod including a shell having an opening on a front side of the outer pod and a door,
wherein the door includes an actuation feature, and
wherein the shell contains a clamping mechanism configured to interface with the actuation feature such that when the door is attached to the shell, the clamping mechanism is driven to clamp the inner pod within the outer pod.

17. The substrate container of claim 16, wherein the actuation feature includes a first magnet and the clamping mechanism includes a second magnet, wherein the clamping mechanism is driven to clamp the inner pod at least in part by the interaction of the first magnet and the second magnet.

18. The substrate container of claim 16, wherein the actuation feature includes an actuation surface configured to contact a part of the clamping mechanism such that the clamping mechanism is driven to clamp the inner pod.

19. The substrate container of claim 16, wherein the clamping mechanism includes a biasing spring configured to release the clamping mechanism when the door is removed from the shell.

20. The substrate container of claim 16, wherein the clamping mechanism includes an arm secured by a pivot, wherein a clamping surface is provided at an end of the arm.

21. The substrate container of claim 16, wherein the inner pod includes one or more reticle retention features, and the clamping mechanism is configured to contact the one or more reticle retention features such the one or more reticle retention features are actuated to clamp a reticle within the inner pod.

22-23. (canceled)

24. A substrate container, comprising:
an inner pod configured to contain a large format reticle, the inner pod including a cover and a baseplate;
an outer pod configured to contain the inner pod, the outer pod including a shell having an opening on a front side of the outer pod, the shell including a clamping mechanism, the clamping mechanism configured such that in a resting state, the clamping mechanism is positioned to clamp the inner pod within the outer pod, and when in an actuated state, the clamping mechanism is positioned such that the inner pod can be removed from the outer pod.

25. The substrate container of claim 24, wherein the clamping mechanism is configured to be placed into the actuated state by application of mechanical force at an actuation interface.

26. The substrate container of claim 25, wherein the actuation interface is provided on a side wall of the shell.

27. The substrate container of claim 25, wherein the actuation interface is provided on a bottom of the shell.

28. The substrate container of claim 25, wherein the actuation interface is provided on a bottom plate attached to the shell.

29. The substrate container of claim 25, wherein the actuation surface is provided between a bottom of the shell and a bottom plate attached to the shell.

30. The substrate container of claim 24, wherein the clamping mechanism includes a shape memory material.

31. The substrate container of claim 24, wherein the clamping mechanism is configured to be placed into the actuated state by application of electrical current to an actuation surface.

32. The substrate container of claim 31, wherein the actuation surface is electrically connected to a shape memory material.

33. The substrate container of claim 31, wherein the actuation surface is located on an exterior of the shell.

34. The substrate container of claim 31, wherein the actuation surface is located in an interior space defined by the shell.

35. The substrate container of claim 24, wherein the clamping mechanism is configured to be placed into the actuated state by application of a magnetic field to an actuation surface.

36. The substrate container of claim 35, wherein the actuation surface includes a magnet.

37. The substrate container of claim 35, wherein the actuation surface is located on an exterior of the shell.

38. The substrate container of claim 35, wherein the actuation surface is located in an interior space defined by the shell.

39. The substrate container of claim 24, wherein the inner pod includes one or more reticle retention features, and the clamping mechanism is configured to contact the one or more reticle retention features such the one or more reticle retention features are actuated to clamp a reticle within the inner pod.

40-43. (canceled)
